(19) United States
(12) Patent Application Publication
(10) Pub. No.: US 2020/0112774 A1
(43) Pub. Date: Apr. 9, 2020

(54) COMMUNICATION MODULE AND PULLER OF THE SAME

(71) Applicant: Delta Electronics, Inc., Taoyuan City (TW)

(72) Inventors: Yi-Jin LEE, Taoyuan City (TW); Chia-Hou LIAO, Taoyuan City (TW)

(21) Appl. No.: 16/170,998

(22) Filed: Oct. 25, 2018

(30) Foreign Application Priority Data
Oct. 9, 2018 (CN) 201811172966.8

(51) Int. Cl. H04Q 1/02; H05K 7/18

(52) U.S. Cl. CPC H04Q 1/025; H05K 7/186

(57) ABSTRACT

A communication module is provided, and is disposed in an equipment cabinet. The communication module includes a module body and a puller. The module body is detachably disposed in the equipment cabinet, and has a surface. The puller is disposed on the module body, and extends outside the surface. The puller includes a puller body and an elastic element, and the elastic element is connected between the puller body and the module body.

### CROSS REFERENCE TO RELATED APPLICATIONS

This application claims priority of China Patent Application No. 201811172966.8, filed Oct. 9, 2018, the entirety of which is incorporated by reference herein.

### BACKGROUND

### Technical Field

The disclosure relates to a communication module, and in particular to a communication module including a puller.

### Description of the Related Art

The information technology (IT) industry is currently flourishing thanks to ongoing developments in technology. In many companies, a large number of communication apparatuses are stored. Generally, for the convenience of storage and management, modularized communication apparatuses are detachably installed in an equipment cabinet, which helps adjust the arrangement of the communication apparatuses. However, as the functionality of these communication apparatuses is continuously being developing, the number and/or weight of the required components is also increasing. Since the weight of a communication module has increased, the difficulty of installing and removing the communication module has also increased. If the communication module is not completely pushed into the equipment cabinet, the electronic components inside the communication module may not fully perform their functions. On the other hand, when a great strength is required to install or remove a communication module, the user may become injured during the operation, or the equipment cabinet and the communication module may become damaged.

### BRIEF SUMMARY

For solving the aforementioned problems, some embodiments of the present disclosure provide a communication module disposed in an equipment cabinet. The communication module includes a module body and a puller. The module body is detachably disposed in the equipment cabinet, and has a surface. The puller is disposed on the module body, and extends out of the surface. The puller includes a puller body and an elastic element, and the elastic element is connected between the puller body and the module body.

In an embodiment, the puller further includes a fastener secured on the module body. The puller body is pivoted on the fastener, and the puller body is rotatable around the fastener. In an embodiment, the puller body further includes a rotating portion and a force-exerting portion. The rotating portion is located around the fastener and pivoted on the fastener. The force-exerting portion is connected to and extends from the rotating portion. In an embodiment, the rotating portion has a curved edge, and the center of the curved edge is substantially located at the position of the fastener. The thickness of the rotating portion is less than the thickness of the force-exerting portion. In an embodiment, the puller further includes a limiting column located on the module body, when the rotating portion is in contact with the limiting column, the angle between the force-exerting portion and the surface of the module body is less than or equal to 90 degrees. The force-exerting portion has a wave-shaped edge. When the extension direction of the force-exerting portion is parallel to the surface of the module body, the wave-shaped edge faces the surface of the module body.

In an embodiment, the puller body further includes an abutting portion configured to abut the equipment cabinet. In an embodiment, the elastic element is an expansion spring, and the expansion spring exerts a pull force to the puller body, wherein the pull force enables the force-exerting portion to rotate away from the surface of the module body. A handle is disposed on the surface of the module body. The puller further includes a barrier, which is located on the module body. The barrier has a hole, and the hole is configured to secure the handle. After the communication module is installed onto the proper position in the equipment cabinet, the puller body abuts the barrier, so that the communication module is not pushed any further towards the back of the equipment cabinet.

In an embodiment, the puller further includes a positioning structure disposed on the module body, and the positioning structure includes a fastener. The puller body is pivoted on the fastener, and the puller body is rotatable around the fastener. In an embodiment, the puller body further includes a rotating portion and a force-exerting portion. The rotating portion is located around the fastener and is pivoted on the fastener. The force-exerting portion is connected to and extends from the rotating portion. The positioning structure further includes a limiting column, when the rotating portion is in contact with the limiting column, the angle between the force-exerting portion and the surface of the module body is less than or equal to 90 degrees. In an embodiment, a handle is disposed on the surface of the module body. The positioning structure further includes a barrier, and the barrier has a hole, which is configured to secure the handle. After the communication module is installed onto the proper position in the equipment cabinet, the puller body abuts the barrier, so that the communication module is not pushed any further towards the back of the equipment cabinet.

Some embodiments of the present disclosure provide a puller disposed on a communication module. The puller includes a puller body and an elastic element. The elastic element is connected between the puller body and a module body of the communication module.

### BRIEF DESCRIPTION OF THE DRAWINGS

The disclosure can be more fully understood by reading the subsequent detailed description and examples with references made to the accompanying drawings, wherein:

FIG. 1 is a perspective view illustrating an equipment cabinet and a communication module in accordance with an embodiment of the present disclosure.

FIG. 2 is a partial perspective view illustrating the equipment cabinet and the communication module shown in FIG. 1.

FIG. 3A is a perspective view illustrating a puller in accordance with an embodiment of the present disclosure.

FIG. 3B is an exploded view illustrating the puller shown in FIG. 3A.

FIGS. 4A to 4C are partial top views illustrating the process of installing the communication module in accordance with an embodiment of the present disclosure.

FIGS. 5A to 5C are partial top views illustrating the process of removing the communication module in accordance with an embodiment of the present disclosure.

### DETAILED DESCRIPTION OF THE DISCLOSURE

The communication modules of some embodiments of the present disclosure are described in the following description. However, it should be appreciated that the following detailed description of some embodiments of the disclosure provides various concepts of the present disclosure which may be performed in specific backgrounds that can vary widely. The specific embodiments disclosed are provided merely to clearly describe the usage of the present disclosure by some specific methods without limiting the scope of the present disclosure.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

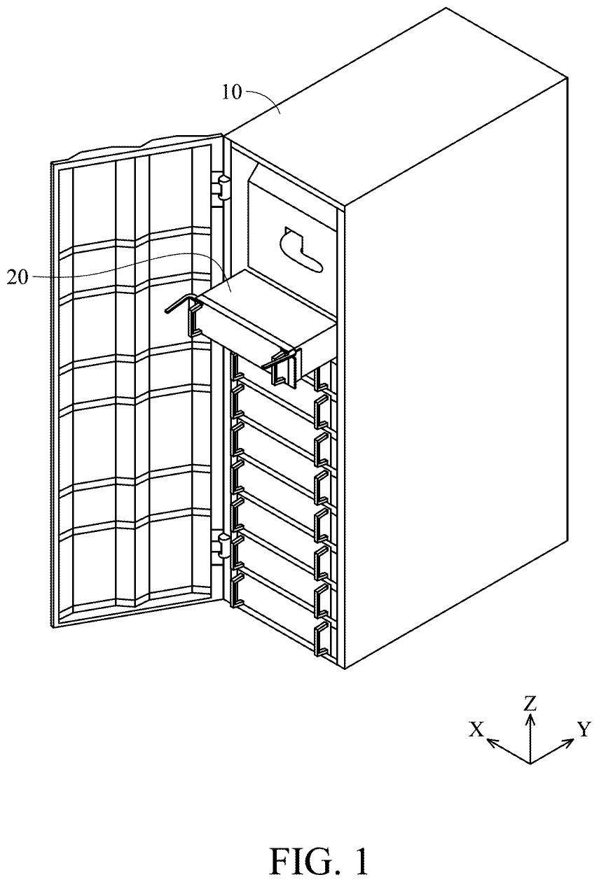

Referring to FIG. 1, FIG. 1 is a perspective view illustrating an equipment cabinet 10 and a communication module 20 in accordance with an embodiment of the present disclosure. As shown in FIG. 1, the communication module 20 may be disposed in the equipment cabinet 10. Generally, various electronic components (not shown) are disposed inside the communication module 20. After multiple communication modules 20 are installed into the equipment cabinet 10, the electronic components of different communication modules 20 may be electrically connected via connectors (not shown), which are located inside the equipment cabinet 10, such that various communication functions are performed.

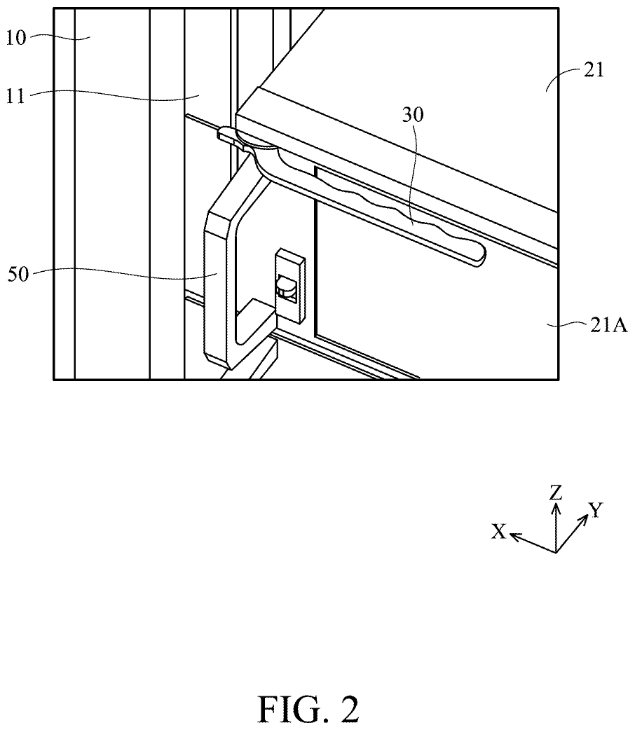

Referring to FIG. 2, FIG. 2 is a partial perspective view illustrating the equipment cabinet 10 and the communication module 20 shown in FIG. 1. It should be noted that for clearly illustrating the connection relationship between the equipment cabinet 10 and the communication module 20, only portions of the equipment cabinet 10 and the communication module 20 are illustrated in this embodiment. As shown in FIG. 2, the communication module 20 mainly includes a module body 21 and a puller 30. The module body 21 is detachably disposed in the equipment cabinet 10, wherein the module body 21 has a surface 21A. When the module body 21 is disposed in the equipment cabinet 10 by a user, the surface 21A is towards the user.

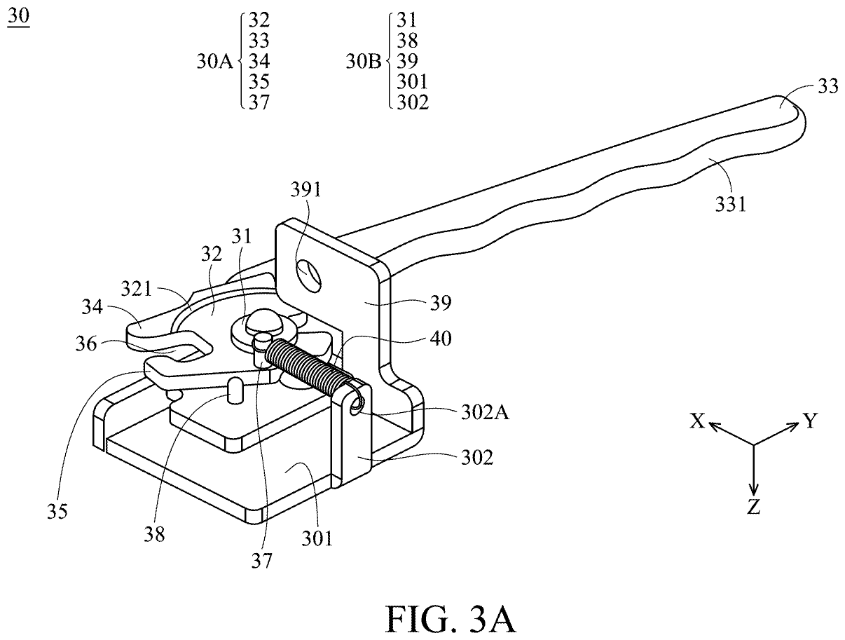

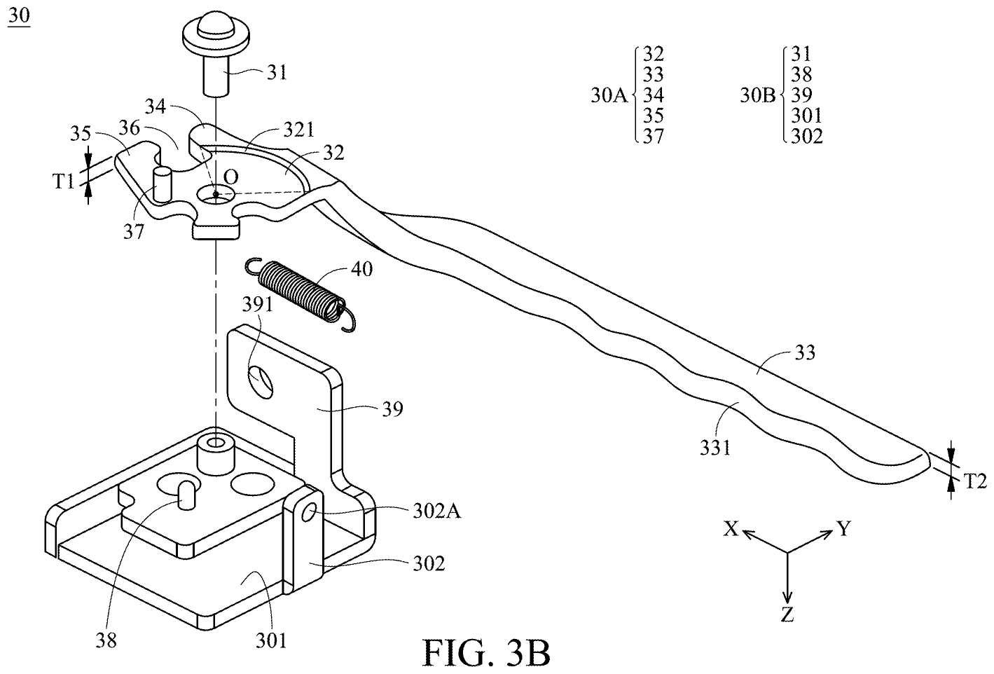

In addition, the equipment cabinet 10 has the engaging portion 11, which is configured to engage with and position with the communication module 20. The puller 30 is connected to the module body 21 and extends out of the surface 21A. In other words, when the module body 21 is disposed in the equipment cabinet 10 by the user, the puller 30 is closer to the user than the module body 21. Further description regarding the detailed structure of the puller 30 will be provided in accompany with FIGS. 3A and 3B as follows. Furthermore, a handle 50 is disposed on the surface 21A of the module body 21, and is configured to assist the user to arrange the communication module 20 in the equipment cabinet 10. It should be appreciated that although only the structure of one side of the communication module 20 is illustrated in this embodiment here, the structure of the other side, which is not illustrated, of the communication module 20 may also include the same or similar components shown in this embodiment. For the sake of simplicity, it will not be repeated in the following paragraphs.

Referring to FIGS. 3A and 3B collectively, FIG. 3A is a perspective view illustrating the puller 30 in accordance with an embodiment of the present disclosure, and FIG. 3B is an exploded view illustrating the puller 30 shown in FIG. 3A. It should be noted that for clearly illustrating the detailed structure of the puller 30, the Z-axis direction in FIGS. 3A and 3B is opposite to the Z-axis direction in FIGS. 1 and 2. In this embodiment, the puller 30 mainly includes a puller body 30A, a positioning structure 30B, and an elastic element 40. The puller body 30A includes a rotating portion 32 and a force-exerting portion 33, wherein the force-exerting portion 33 is connected to and extends from the rotating portion 32. The positioning structure 30B is disposed on the module body 21 (shown in FIG. 2), so that the puller 30 may be combined with the module body 21. The positioning structure 30B includes a fastener 31, a limiting column 38, and a barrier 39. The rotating portion 32 is located around and pivoted on the fastener 31, and thereby the puller body 30A may be rotated around the fastener 31. When the rotating portion 32 is in contact with the limiting column 38, an angle between the force-exerting portion 33 and the surface 21A of the module body 21 is less than or equal to 90 degrees. The rotating portion 32 has a curved edge 321, and a center O of the curved edge 321 is substantially located at the position of the fastener 31. In addition, one side of the force-exerting portion 33 has a wave-shaped edge 331.

Furthermore, the puller body 30A further includes a first abutting portion 34 and a second abutting portion 35, which are configured to abut the engaging portion 11 of the equipment cabinet 10 when the communication module 20 is installed. The first abutting portion 34 and the second abutting portion 35 are connected to the rotating portion 32, and a concave 36 is formed between the first abutting portion 34 and the second abutting portion 35. The puller body 30A further includes a protruding column 37, which is located on the rotating portion 32. In addition, the positioning structure 30B further includes a barrier 39. In this embodiment, the barrier 39 is perpendicular to the module body 21. In this embodiment, the barrier 39 has a hole 391, which is configured to secure the handle 50 (shown in FIG. 2) on the surface 21A of the module body 21, but it is not limited thereto. In other embodiments, the hole 391 may also be replaced with other structures which may secure the handle 50 on the module body 21.

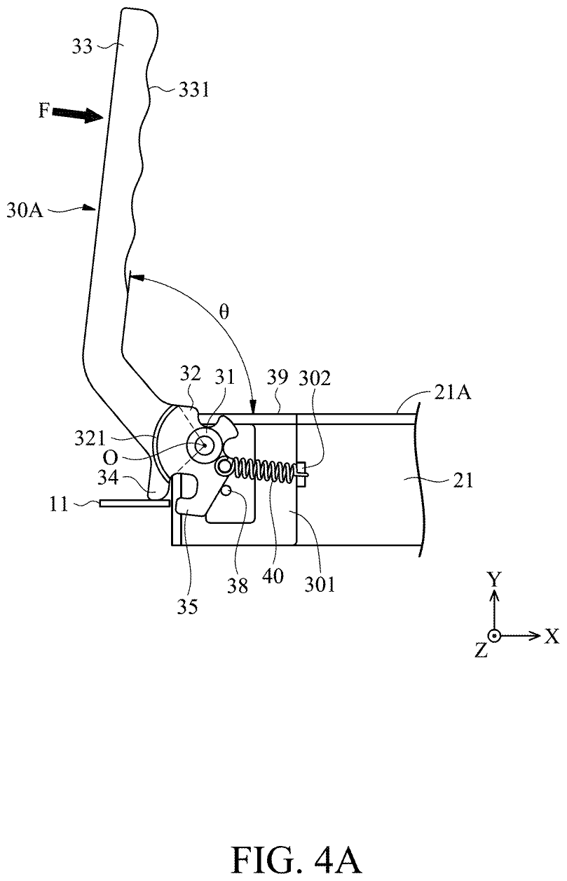

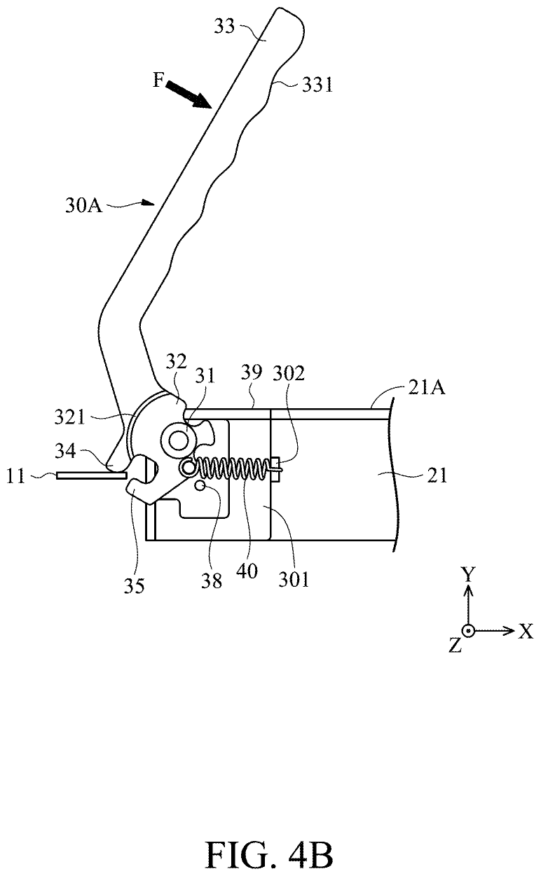

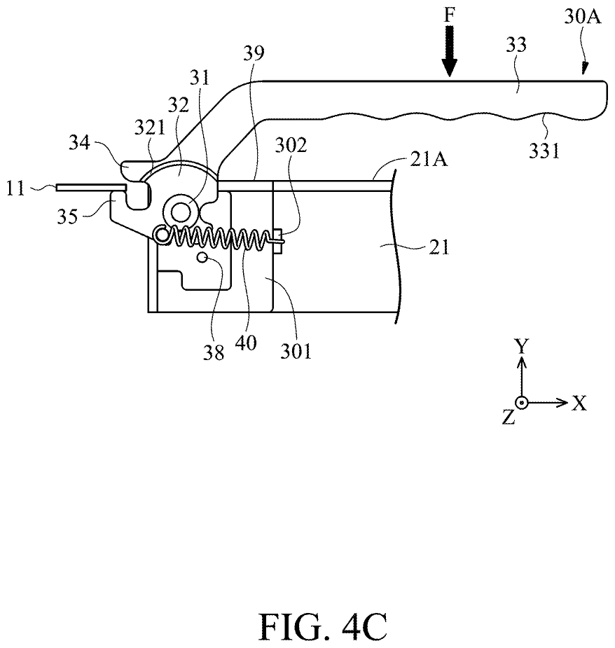

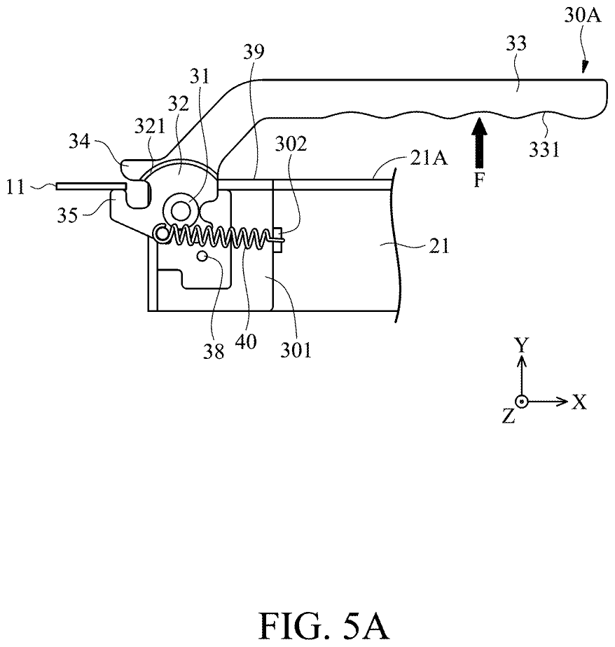

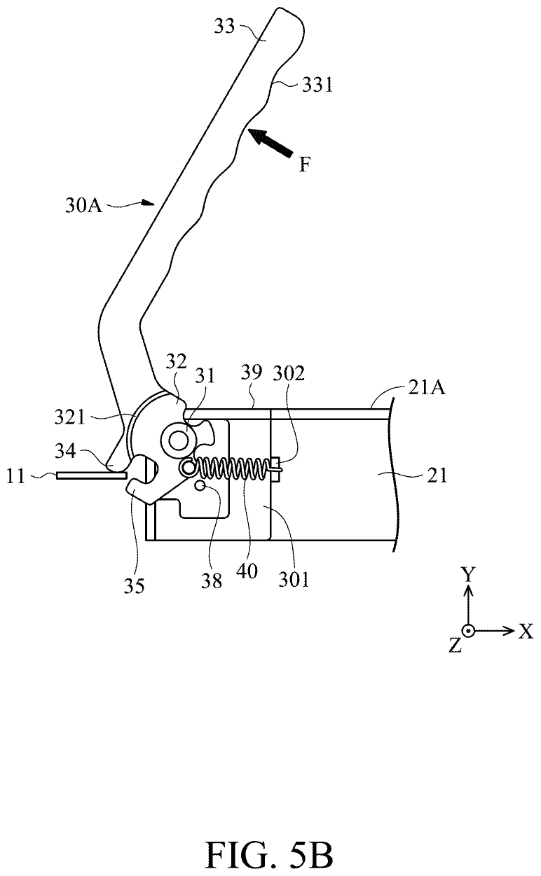

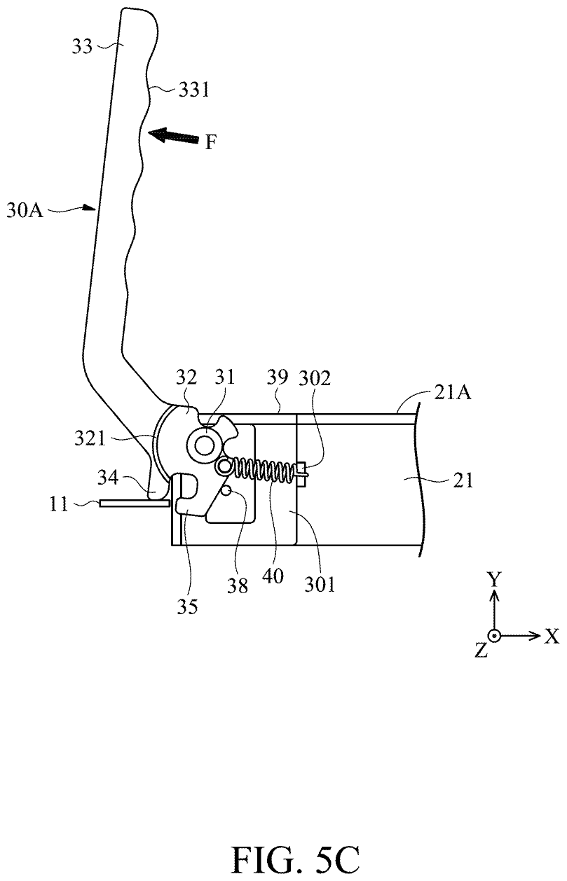

Moreover, the elastic element 40 of the puller 30 is connected between the puller body 30A and the module body 21. In this embodiment, the positioning structure 30B further includes a protruding portion 302. The protruding portion 302 has an opening 302A, and the elastic element 40 is connected between the protruding column 37 and the opening 302A of the protruding portion 302. For example, the elastic element 40 is an expansion spring, which is configured to exert a pull force to the puller body 30A. That way, the force-exerting portion 33 of the puller body 30A may be rotated around the fastener 31 and away from the surface 21A (shown in FIG. 2). The detailed process regarding the rotation of the puller body 30A will be further discussed in accompany with FIGS. 4A to 4C and 5A to 5C as follows.

In this embodiment, the positioning structure 30B includes a plate 301, a fastener 31, the limiting column 38, the barrier 39, and the protruding portion 302. The plate 301 is disposed and overlaid on an upper surface of the module body 21 (FIG. 2), and the fastener 31, the limiting column 38, the barrier 39, and the protruding portion 302 are all connected to the plate 301, and extend from the plate 301 towards a direction, which is away from the upper surface of the module body 21. However, they are not limited therein. In other embodiments, the plate 301 may be omitted. That is, the fastener 31, the limiting column 38, the barrier 39, and the protruding portion 302 may be directly disposed on the upper surface of the module body 21. In other words, the fastener 31, the limiting column 38, and the barrier 39 may be directly secured on the module body 21, or secured on the module body 21 via the plate 301.

As shown in FIG. 3B, a first thickness T1 of the rotating portion 32 is less than a second thickness T2 of the force-exerting portion 33. By the above design, the rotating portion 32 may not be in contact with the equipment cabinet 10 during the rotation. Therefore, the equipment cabinet 10, the puller 30 and/or the electronic components disposed inside the module body 21 are prevented from damage. In addition, for achieving the above effect, the thickness of the second abutting portion 35 is equal to the first thickness T1 of the rotating portion 32. The thickness of the first abutting portion 34 may be equal to the second thickness T2 of the force-exerting portion 33. In this embodiment, for the convenience of exerting force, the force-exerting portion 33 and the rotating portion 32 are located on different horizontal planes (X-Y planes). That is, the position of the force-exerting portion 33 is higher than the position of the rotating portion 32. However, in some other embodiments, the force-exerting portion 33 and the rotating portion 32 may be disposed on the same horizontal plane according to design demands.

Referring to FIG. 4A, FIG. 4A is a partial top view illustrating the communication module 20 before the installation is completed in accordance with an embodiment of the present disclosure. It should be noted that for the sake of simplicity, the complete structure of the equipment cabinet 10 will not be fully illustrated in the following figures. Instead, only the engaging portion 11 of the equipment cabinet 10 is illustratively shown, and the bottoms of the following figures represent the interior of the equipment cabinet 10. As shown in FIG. 4A, since the pull force generated by the elastic element 40 may pull the puller body 30A, when the communication module 20 is not installed into the equipment cabinet 10, the rotating portion 32 of the puller body 30A may be in contact with the limiting column 38. At this time, an angle θ between the force-exerting portion 33 and the surface 21A (i.e. the angle between one side, which is close to the surface 21A, of the force-exerting portion 33, and the surface 21A) may be less than or equal to 90 degrees (85 degrees in this embodiment). When the communication module 20 is pushed into the equipment cabinet 10, the first abutting portion 34 may abut the engaging portion 11 of the equipment cabinet 10 at first. A force (shown as an arrow F) may be exerted to the force-exerting portion 33 by the user, who pushes the force-exerting portion 33 towards the surface 21A of the module body 21.

Referring to FIG. 4B, FIG. 4B is a partial top view illustrating the communication module 20 during the installation process. As shown in FIG. 4B, since the force shown as the arrow F is greater than the pull force generated by the elastic element 40, the force-exerting portion 33 of the puller body 30A begins to rotate towards the surface 21A of the module body 21 (along the clockwise direction). The rotating portion 32 is separated from the limiting column 38, and the module body 21 may be moved towards the interior of the equipment cabinet 10.

Next, referring to FIG. 4C, FIG. 4C is a partial top view illustrating the communication module 20 after the installation is completed. As shown in FIG. 4C, after the installation of the communication module 20 is completed, the second abutting portion 35 may abut the engaging portion 11 of the equipment cabinet 10. The extension direction (X-axis direction) of the force-exerting portion 33 may be parallel to the surface 21A of the module body 21, and the wave-shaped edge 331 of the force-exerting portion 33 may face the surface 21A. Meanwhile, the communication module 20 is installed onto the proper position in the equipment cabinet 10. The puller body 30A abuts the barrier 39, so that the communication module 20 cannot be pushed any further towards the back of the equipment cabinet 10. That is, the barrier 39 has a limiting effect (the puller body 30A is limited by the barrier 39), so that the user may realize that the communication module 20 has been installed onto the correct position in the equipment cabinet 10 and stop exerting force. Therefore, the communication module 20 may be prevented from being pushed into the equipment cabinet 10 too much by the user, causing improper connection between the electronic components inside the communication module 20 and the equipment cabinet 10 so that those electronic components may not perform their original functionalities.

In addition, it should be noted that although after the communication module 20 is disposed in the equipment cabinet 10, the user may not exert force to the puller body 30A, however, the pull force generated by the elastic element 40 may not overcome the friction force between the equipment cabinet 10 and the communication module 20. In other words, the friction force generated between the equipment cabinet 10 and the communication module 20 is equal to the pull force of the elastic element 40. Therefore, under the aforementioned circumstances, the pull force of the elastic element 40 cannot force the puller body 30A to rotate, and is certainly not enough to remove the communication module 20 from the equipment cabinet 10. The force-exerting portion 33 is maintained in a closed state, where the force-exerting portion 33 is parallel to the surface 21A of the module body 21.

Then, referring to FIG. 5A, FIG. 5A is a partial top view illustrating the communication module 20 before removing from the equipment cabinet 10 in accordance with an embodiment of the present disclosure. As shown in FIG. 5A, since the force-exerting portion 33 is located in front of the surface 21A of the module body 21, there is a gap between the force-exerting portion 33 and the surface 21A. The gap helps the user to exert forces to the force-exerting portion 33 in the direction shown as the arrow F. In addition, because the edge, which faces the surface 21A, of the force-exerting portion 33 is designed with a wave-shape (such as the wave-shaped edge 331), further helping the user to exert forces to the force-exerting portion 33. It should be appreciated that in some other embodiments, the force-exerting portion 33 may be designed to have any other structure which meets ergonomics, and thereby the user may avoid getting hurt during the operation.

Referring to FIG. 5B, FIG. 5B is a partial top view illustrating the communication module 20 during the removal process. As shown in FIG. 5B, a force is exerted to the force-exerting portion 33 in the direction shown as the arrow F, the force-exerting portion 33 of the puller body 30A begins to rotate away from the surface 21A of the module body 21 (along the counter-clockwise direction). The second abutting portion 35 may be separated from the engaging portion 11 of the equipment cabinet 10, and the first abutting portion 34 abuts the engaging portion 11 of the equipment cabinet 10. Therefore, the module body 21 may be gradually removed from the equipment cabinet 10 (i.e. the module body 21 moves towards the Y-axis direction in FIG. 5B).

Next, referring to FIG. 5C, FIG. 5C is a partial top view illustrating the communication module 20 after the removal is completed. As shown in FIG. 5C, after the removal of the communication module 20 is completed, the rotating portion 32 of the puller body 30A may be in contact with the limiting column 38 again because of the force exerted by the user and the pull force generated by the elastic element 40. By the arrangement of the elastic element 40, before next installation of the communication module 20, the puller body 30A may be maintained at the proper operation position. Therefore, it is avoided that the user perform the operation using the puller 30 in an incorrect position and/or angle, causing damage to the equipment cabinet 10, the puller 30 and/or the electronic components disposed inside the module body 21, or even causing danger to the user in the operation.

It should be noted that in the aforementioned embodiments, the puller 30 connected to one side of the module body 21 serves as an example to discuss the operating direction of the puller 30, but it is not intended to limit the present disclosure. For example, the puller 30 (not shown) connected to the other side of the module body 21 may be operated in a rotating direction, which is different from the rotating direction of the puller 30 in the aforementioned embodiments.

As set forth above, the present disclosure provides a communication module including a puller. By the arrangement of the puller, it may be simpler to arrange the communication module in the equipment cabinet, or remove the communication module from the equipment cabinet. In addition, when the puller abuts the equipment cabinet, the user may immediately realize that the communication module has been installed onto the correct position in the equipment cabinet. Therefore, the positioning effect is achieved.

Moreover, the puller is maintained at the proper position before the installation via the limiting column and the elastic element of the puller, wherein the elastic element is connected between the puller body and the module body. In the aforementioned design, when the communication module is disposed in the equipment cabinet, the puller does not collide with the equipment cabinet. Therefore, the equipment cabinet, the puller, and/or the electronic components disposed inside the module body are prevented from damage.

While the embodiments and the advantages of the present disclosure have been described above, it should be understood that those skilled in the art may make various changes, substitutions, and alterations to the present disclosure without departing from the spirit and scope of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. As long as those may perform substantially the same function in the aforementioned embodiments and obtain substantially the same result, they may be used in accordance with some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

1. A communication module disposed in an equipment cabinet, comprising:
a module body, detachably disposed in the equipment cabinet, having a surface; and
a puller, disposed on the module body, extending out of the surface, wherein the puller comprises a puller body and an elastic element, and the elastic element is connected between the puller body and the module body,
wherein the elastic element is an expansion spring, the expansion spring exerts a pull force to the puller body, and the pull force enables the puller body to rotate away from the surface of the module body,
wherein the puller further comprises a fastener, and the elastic element drives the puller body to rotate around the fastener.

2. The communication module as claimed in claim 1, wherein the fastener is secured on the module body, and the puller body is pivoted on the fastener.

3. The communication module as claimed in claim 2, wherein the puller body further comprises:
a rotating portion located around the fastener and pivoted on the fastener; and
a force-exerting portion connected to and extending from the rotating portion.

4. The communication module as claimed in claim 3, wherein the rotating portion has a curved edge, and a center of the curved edge is substantially located at a position of the fastener.

5. The communication module as claimed in claim 3, wherein a thickness of the rotating portion is less than a thickness of the force-exerting portion.

6. The communication module as claimed in claim 3, wherein the puller further comprises a limiting column located on the module body, and when the rotating portion is in contact with the limiting column, an angle between the force-exerting portion and the surface of the module body is less than or equal to 90 degrees.

7. The communication module as claimed in claim 3, wherein the force-exerting portion has a wave-shaped edge, and when an extension direction of the force-exerting portion is parallel to the surface of the module body, the wave-shaped edge faces the surface of the module body.

8. The communication module as claimed in claim 1, wherein the puller body further comprises an abutting portion configured to abut the equipment cabinet.

9. (canceled)

10. The communication module as claimed in claim 1, wherein a handle is disposed on the surface of the module body.

11. The communication module as claimed in claim 10, wherein the puller further comprises a barrier located on the module body, the barrier has a hole, and the hole is configured to secure the handle.

12. The communication module as claimed in claim 1, wherein the puller further comprises a barrier located on the module body, and after the communication module is installed onto a proper position in the equipment cabinet, the puller body abuts the barrier, so that the communication module is not pushed any further towards a back of the equipment cabinet.

13. The communication module as claimed in claim 1, wherein the puller further comprises a positioning structure disposed on the module body, and the positioning structure comprises:
a fastener, wherein the puller body is pivoted on the fastener, and the puller body is rotatable around the fastener.

14. The communication module as claimed in claim 13, wherein the puller body further comprises a rotating portion and a force-exerting portion, the rotating portion is located around and pivoted on the fastener, the force-exerting portion is connected to and extends from the rotating portion, and the positioning structure further comprises a limiting column, and when the rotating portion is in contact with the limiting column, an angle between the force-exerting portion and the surface of the module body is less than or equal to 90 degrees.

15. The communication module as claimed in claim 13, wherein a handle is disposed on the surface of the module body, the positioning structure further comprises a barrier, and the barrier has a hole configured to secure the handle, and after the communication module is installed onto a proper position in the equipment cabinet, the puller body abuts the barrier, so that the communication module is not pushed any further towards a back of the equipment cabinet.

16. A puller disposed on a communication module, comprising:
a puller body;
an elastic element connected between the puller body and a module body of the communication module, wherein the elastic element is an expansion spring, the expansion spring exerts a pull force to the puller body, and the pull force enables a force-exerting portion of the puller body to rotate away from a surface of the module body; and
a fastener, wherein the elastic element drives the puller body to rotate around the fastener.
